(19) United States
(12) Patent Application Publication
(10) Pub. No.: US 2026/0129966 A1
(43) Pub. Date: May 7, 2026

(54) SHIFTED STACKED FETS

(71) Applicant: INTERNATIONAL BUSINESS MACHINES CORPORATION, Armonk, NY (US)

(72) Inventors: Debarghya Sarkar, Latham, NY (US); Ruilong Xie, Niskayuna, NY (US); Julien Frougier, Albany, NY (US); Huimei Zhou, Albany, NY (US); Shogo Mochizuki, Mechanicville, NY (US)

(21) Appl. No.: 18/935,982

(22) Filed: Nov. 4, 2024

(51) Int. Cl. H01L 27/092; H01L 21/822; H01L 21/8238; H01L 23/528; H01L 29/06; H01L 29/417; H01L 29/423; H01L 29/66; H01L 29/775; H01L 29/786

(52) U.S. Cl. CPC H10D 84/856; H10D 30/014; H10D 30/43; H10D 30/6729; H10D 30/6735; H10D 30/6757; H10D 62/121; H10D 64/017; H10D 84/017; H10D 84/0186; H10D 84/038; H10D 88/01; H10W 20/427

(57) ABSTRACT

A semiconductor device includes a first transistor in a first stacked level and a second transistor in a second stacked level. A first active region of the first transistor is shifted with respect to a second active region of the second transistor. A first dielectric bar confines the first active region on one side. A second dielectric bar confines the second active region on one side, wherein the first dielectric bar is on an opposite side of the second dielectric bar.

### BACKGROUND

The present invention generally relates to semiconductor devices and processing methods, and more particularly to stacked field effect transistors (FETs) shifted between stacked layers to reduce layout area needed for contacts.

Stacked transistor devices may be used to increase areal density of devices on a chip.

Additionally, the close proximity of the overlying and underlying devices can be useful when forming paired devices, such as complementary semiconductor devices that include two devices of opposing polarity. However, positioning transistors above one another places spatial and electrical constraints that can make it challenging to provide required performance.

An electrical constraint arises when attempting to connect to source/drain regions on different stack levels. Areal space is needed for contacts that bypass one level and connect to another level. The areal space for the contacts needs to account for adequate conduction of the contact and adequate dielectric protection around the contacts to prevent short circuits. Therefore, a need exists for wiring patterns that can connect to source/drain regions on different stack levels while minimizing consumed layout area.

### SUMMARY

In accordance with an embodiment of the present invention, a semiconductor device includes a first transistor in a first stacked level and a second transistor in a second stacked level. A first active region of the first transistor is shifted with respect to a second active region of the second transistor. A first dielectric bar confines the first active region on one side. A second dielectric bar confines the second active region on one side, wherein the first dielectric bar is on an opposite side of the second dielectric bar.

In other embodiments, a frontside deep contact can extend through the first stacked level to connect with the second active region. A backside deep contact can extend through the second stacked level to connect with the first active region. Adjacent first dielectric bars can bound a wiring channel that permits passage of contacts, with electrical isolation, past the first active region. Adjacent second dielectric bars can bound a wiring channel that permits passage of contacts, with electrical isolation, past the second active region. Backside power rails can be formed on a backside of the semiconductor device and electrically connected to at least one of the first active region and the second active region.

In accordance with another embodiment of the present invention, a semiconductor device, includes a first transistor level including first source/drain regions and a second transistor level including second source/drain regions, the second transistor level being stacked over the first transistor level. The first source/drain regions are shifted with respect to the second source/drain regions, and the first source/drain regions are confined on one side by first dielectric bars and the second source/drain regions are confined on one side by second dielectric bars. The first dielectric bars are on an opposite side of the second dielectric bars relative to respective source/drain regions.

In other embodiments, a frontside deep contact can extend through the first transistor level to connect with a second source/drain region. A backside deep contact can extend through the second transistor level to connect with a first source/drain region. Adjacent first dielectric bars can bound a wiring channel that permits passage of contacts, with electrical isolation, past a first source/drain region. Adjacent second dielectric bars can bound a wiring channel that permits passage of contacts, with electrical isolation, past a second source/drain region. Backside power rails can be formed on a backside of the semiconductor device and electrically connected to at least one source/drain region. The first source/drain regions and first dielectric bars can follow a first alternating pattern in the first transistor level. The second source/drain regions and second dielectric bars can follow a second alternating pattern in the second transistor level. The first alternating pattern and the second alternating pattern can be offset from each other. Gate structures can be formed on the first transistor level and on the second transistor level, the gate structures including a shared connection between the gate structures of the first transistor level and the gate structures of the second transistor level. The gate structures at the first transistor level (and/or second transistor level) can include gate electrodes that encapsulate the first dielectric bars.

In accordance with another embodiment of the present invention, a semiconductor device includes first transistors in a first stacked level and second transistors in a second stacked level. First source/drain regions of the first transistors are shifted with respect to second source/drain regions of the second transistors, wherein the first source/drain regions are confined on one side by first dielectric bars and the second source/drain regions are confined on one side by second dielectric bars, the first dielectric bars being on an opposite side of the second dielectric bars relative to respective source/drain regions. Wiring channels on one stacked level are aligned with unconfined sides of source/drain regions on an adjacent stacked level.

In other embodiments, the wiring channels can be bound by first dielectric bars on one stacked level and the second dielectric bars on another stacked level. A deep contact can extend through one stacked level through a wiring channel to connect with a source/drain region on another stacked level.

These and other features and advantages will become apparent from the following detailed description of illustrative embodiments thereof, which is to be read in connection with the accompanying drawings.

### BRIEF DESCRIPTION OF THE DRAWINGS

The following description will provide details of preferred embodiments with reference to the following figures, wherein:

FIG. 1 shows a cross-sectional view of a semiconductor substrate and a stack of layers that can be formed or provided in one or more nanosheets, in accordance with an embodiment of the present invention;

FIG. 2 shows a cross-sectional view of the stack of layers patterned, in accordance with an embodiment of the present invention;

FIG. 3 shows a cross-sectional view after spacers (dielectric bars) are formed, in accordance with an embodiment of the present invention;

FIG. 4 shows a cross-sectional view after formation of a mask using an organic planarization layer is formed for etching the stacks of layers a second time, in accordance with an embodiment of the present invention;

FIG. 5 shows a cross-sectional view after shallow trench isolation regions are formed, in accordance with an embodiment of the present invention;

FIG. 6 shows a cross-sectional view after bottom source/drain regions are epitaxially grown, in accordance with an embodiment of the present invention;

FIG. 7 shows a cross-sectional view after a dielectric layer (e.g., an interlayer dielectric) is formed over the bottom source/drain regions, in accordance with an embodiment of the present invention;

FIG. 8 shows a cross-sectional view after a bonding layer and a top stack of layers (e.g., a nanosheet) are applied over the dielectric layer, in accordance with an embodiment of the present invention;

FIG. 9 shows a cross-sectional view after a top stack is patterned and spacers (dielectric bars) are formed, in accordance with an embodiment of the present invention;

FIG. 10 shows a cross-sectional view after top source/drain regions are epitaxially grown and a dielectric layer is formed, in accordance with an embodiment of the present invention;

FIG. 11 shows a cross-sectional view after top contacts and a back end of line layer are formed and a carrier wafer is applied to a top of the dielectric layer, in accordance with an embodiment of the present invention;

FIG. 12 shows a cross-sectional view after the structure is flipped to process a backside and the substate is removed to an etch stop layer, in accordance with an embodiment of the present invention;

FIG. 13 shows a cross-sectional view after a semiconductor layer is removed from the backside and a dielectric layer is formed in a space occupied by the semiconductor layer, in accordance with an embodiment of the present invention;

FIG. 14 shows a cross-sectional view after the dielectric layer on the backside is etched to open contact holes or trenches to form contacts therein, in accordance with an embodiment of the present invention;

FIG. 15 shows a cross-sectional view after backside power rails and a backside interconnect layer are formed, in accordance with an embodiment of the present invention; and

FIG. 16 shows a cross-sectional view of gate structures formed, in accordance with an embodiment of the present invention.

### DETAILED DESCRIPTION

In accordance with embodiments of the present invention, devices and methods are described which include stacked field effect transistors that offset between levels of each stack. The offset provides enough shift to enable adequate-sized contacts and provide scaling benefits that include reduced layout area. In an embodiment, a first transistor in a first stacked level is stacked over a second transistor in a second stacked level. An active region (e.g., source/drain region or S/D region) of the first transistor is shifted with respect to an active region (e.g., source/drain region or S/D region) of the second transistor. The active region of the first transistor is confined on one side by a dielectric bar and unconfined on a side opposite the dielectric bar. Similarly, the active region of the second transistor is confined on one side by another dielectric bar and unconfined on a side opposite the dielectric bar. The dielectric bar that confines the active region of the first transistor is on an opposite side of the dielectric bar that confines the active region of the second transistor, e.g., on an opposite side relative to respective source/drain regions.

Spaces between dielectric bars on each level of the stack provide a path for routing wires or contacts between S/D regions on one level passed S/D regions on another level. For example, a frontside deep contact can land over a bottom S/D region on a non-confined side. The frontside deep contact can be isolated from a top S/D region by top level dielectric bars. Likewise, a backside deep contact can land on a top S/D region on a non-confined side. The backside deep contact can be isolated from the bottom S/D region by bottom dielectric bars.

A method of forming a semiconductor device includes forming bottom devices with each S/D region confined by a dielectric bar at one side, and not confined at the other side. Top devices are formed with each S/D region confined by a dielectric bar at one side and not confined at the other side. The dielectric bars are formed on opposite sides of the respective S/D regions between levels. Frontside deep contacts can be formed that connect to a bottom S/D region on a non-confined side. Backside deep contacts can be formed that connect to a top S/D region on a non-confined side.

The dielectric bars on a given level can follow a first alternating pattern that alternates between a wiring channel and adjacent S/D regions. On an adjacent level to the given level, a second alternating pattern is opposite to that of the first alternating pattern. This means that where the first alternating pattern calls for a wiring channel the second alternating pattern calls for adjacent S/D regions. Other alternating patterns are also contemplated, e.g., the patterns can double the frequency of wiring channels or adjacent S/D regions or both, etc.

In accordance with an embodiment of the present invention, a semiconductor device includes a first transistor in a first stacked level and a second transistor in a second stacked level. A first active region of the first transistor is shifted with respect to a second active region of the second transistor. A first dielectric bar confines the first active region on one side. A second dielectric bar confines the second active region on one side, wherein the first dielectric bar is on an opposite side of the second dielectric bar.

In other embodiments, a frontside deep contact can extend through the first stacked level to connect with the second active region. A backside deep contact can extend through the second stacked level to connect with the first active region. Adjacent first dielectric bars can bound a wiring channel that permits passage of contacts, with electrical isolation, past the first active region. Adjacent second dielectric bars can bound a wiring channel that permits passage of contacts, with electrical isolation, past the second active region. Backside power rails can be formed on a backside of the semiconductor device and electrically connected to at least one of the first active region and the second active region.

In accordance with another embodiment of the present invention, a semiconductor device, includes a first transistor level including first source/drain regions and a second transistor level including second source/drain regions, the second transistor level being stacked over the first transistor level. The first source/drain regions are shifted with respect to the second source/drain regions, and the first source/drain regions are confined on one side by first dielectric bars and the second source/drain regions are confined on one side by second dielectric bars. The first dielectric bars are on an opposite side of the second dielectric bars relative to respective source/drain regions.

In other embodiments, a frontside deep contact can extend through the first transistor level to connect with a second source/drain region. A backside deep contact can extend through the second transistor level to connect with a first source/drain region. Adjacent first dielectric bars can bound a wiring channel that permits passage of contacts, with electrical isolation, past a first source/drain region. Adjacent second dielectric bars can bound a wiring channel that permits passage of contacts, with electrical isolation, past a second source/drain region. Backside power rails can be formed on a backside of the semiconductor device and electrically connected to at least one source/drain region. The first source/drain regions and first dielectric bars can follow a first alternating pattern in the first transistor level. The second source/drain regions and second dielectric bars can follow a second alternating pattern in the second transistor level. The first alternating pattern and the second alternating pattern can be offset from each other. Gate structures can be formed on the first transistor level and on the second transistor level, the gate structures including a shared connection between the gate structures of the first transistor level and the gate structures of the second transistor level. The gate structures at the first transistor level (and/or second transistor level) can include gate electrodes that encapsulate the first dielectric bars.

In accordance with another embodiment of the present invention, a semiconductor device includes first transistors in a first stacked level and second transistors in a second stacked level. First source/drain regions of the first transistors are shifted with respect to second source/drain regions of the second transistors, wherein the first source/drain regions are confined on one side by first dielectric bars and the second source/drain regions are confined on one side by second dielectric bars, the first dielectric bars being on an opposite side of the second dielectric bars relative to respective source/drain regions. Wiring channels on one stacked level are aligned with unconfined sides of source/drain regions on an adjacent stacked level.

In other embodiments, the wiring channels can be bound by first dielectric bars on one stacked level and the second dielectric bars on another stacked level. A deep contact can extend through one stacked level through a wiring channel to connect with a source/drain region on another stacked level.

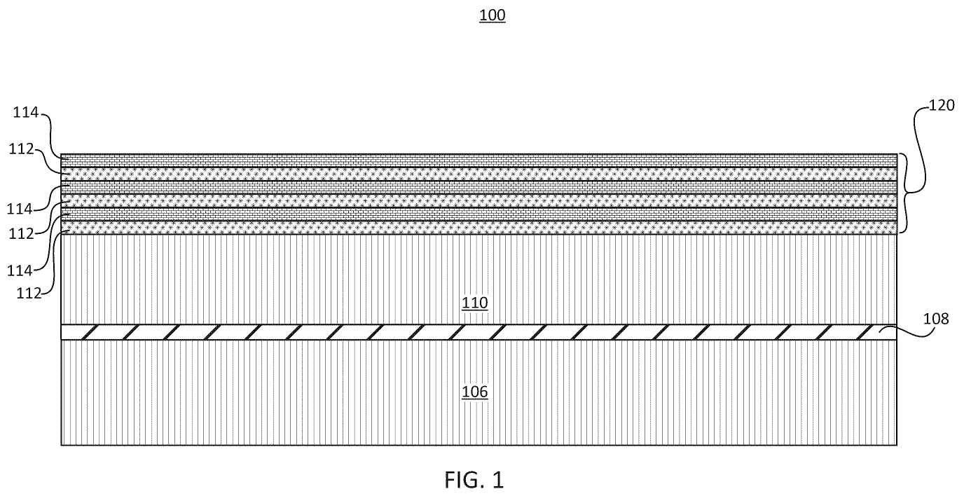

Referring now to the drawings in which like numerals represent the same or similar elements and initially to FIG. 1, devices and methods for manufacturing a stacked field effect transistor (FET) device are shown in accordance with embodiments of the present invention. A wafer 100 includes a substrate 106 on which the stacked FET device will be fabricated.

The substrate 106 can include any suitable substrate structure, e.g., a bulk semiconductor, a semiconductor-on-insulator (SOI) substrate, etc., and preferably includes a monocrystalline semiconductor. In one example, the substrate 106 can include a silicon-containing material.

Illustrative examples of Si-containing materials suitable for the substrate 106 can include, but are not limited to, Si, SiGe, SiGeC, SiC and multi-layers thereof. Although silicon is the predominantly used semiconductor material in wafer fabrication, alternative semiconductor materials can be employed as additional layers, such as, but not limited to, germanium, gallium arsenide, gallium nitride, silicon germanium, cadmium telluride, zinc selenide, etc.

An etch stop layer 108 is formed on the substrate 106. The etch stop layer 108 can include an epitaxially grown crystal structure. The etch stop layer 108 includes a material that permits the selective etching and removal the substrate 106 in later steps. In an embodiment, the etch stop layer 108 includes SiGe although depending on the material of the substrate 106, other materials can be selected, e.g., SiGeC, SiC, etc.

A semiconductor layer 110 is epitaxially grown on the etch stop layer 108. The semiconductor layer 110 can include a same material as the substrate 106, although other semiconductor materials can be employed, e.g., SiGe, SiGeC, SiC, etc.

A layer stack or stacks 120 are applied to or formed on the semiconductor layer 110. In an embodiment, one or more nanosheets (NS) are applied to the semiconductor layer 110. In another embodiment, the layer stacks can be epitaxially grown using different chemistries to form layers having different properties. In an embodiment, a layer stack 120 includes a semiconductor layer 112 followed by a semiconductor layer 114, a semiconductor layer 112, a semiconductor layer 114, and so on.

Each of semiconductor layers 112 and 114 are selectively removeable relative to the other, e.g., by a selective etching process. In an embodiment, semiconductor layer 112 includes SiGe, where Ge is greater than about 30 atomic % of the compound; and semiconductor layer 114 includes Si. It should be understood that other materials or atomic percentages can be employed for semiconductor layers 112, 114. In other embodiments, different stack orders and numbers may be employed for semiconductor layers 112, 114.

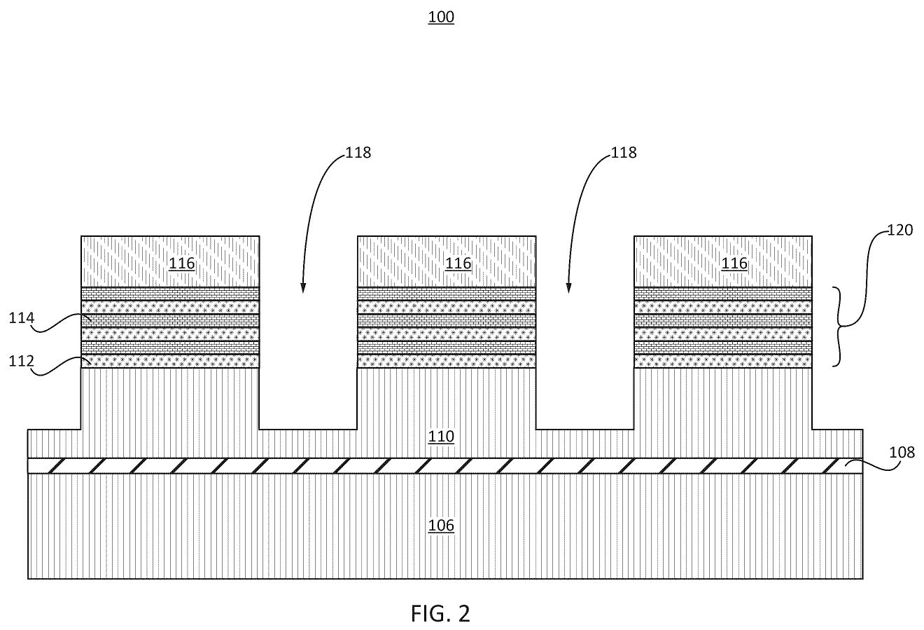

Referring to FIG. 2, the stack 120 can be patterned to expose and etch the semiconductor layer 110. In an embodiment, a hard mask 116 may be formed by blanket depositing a layer of hard mask material, providing a patterned photoresist on top of the layer of hard mask material, and then etching the layer of hard mask material to provide the hard mask pattern for etching the stack 120 and a portion of the semiconductor layer 110. The patterned photoresist can be produced by applying a blanket photoresist layer to the surface of the hard mask 116 and exposing the photoresist layer to a pattern of radiation, and then developing the pattern into the photoresist layer utilizing resist developer. The pattern in the photoresist layer is transferred to the hard mask 116 by an etch process.

Openings 118 are formed through stack 120. Openings 118 can be formed using an anisotropic etch process, such as a reactive ion etch (RIE) or an ion beam etch (IBE). Semiconductor layer 110 is further etched to form trenches therein in accordance with openings 118.

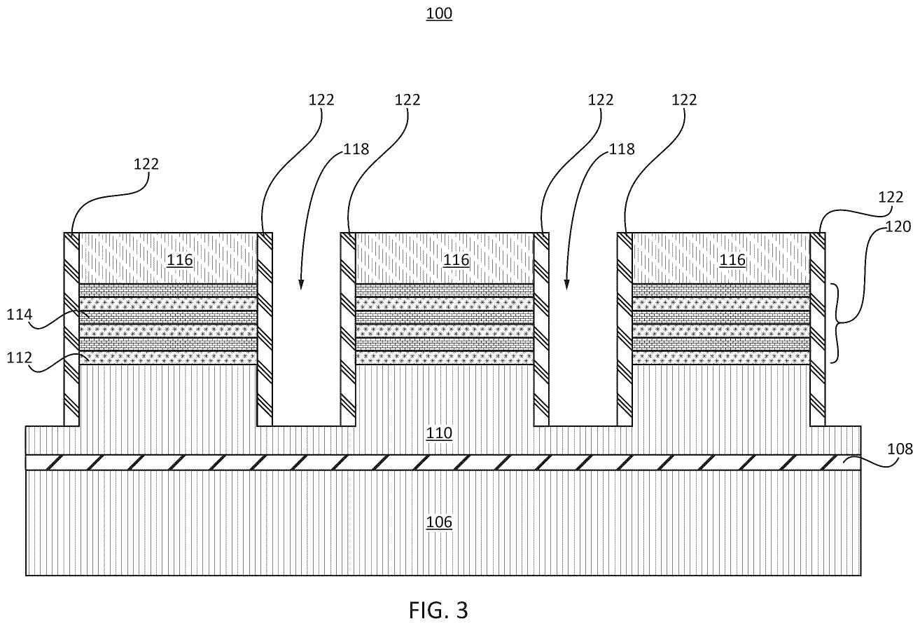

Referring to FIG. 3, a deposition process is employed to form spacers 122. Spacers 122 can include an oxide, such as silicon dioxide, although other dielectric materials can be employed. The deposition process can include a chemical vapor deposition (CVD), although other methods can be employed. The deposition is followed by a spacer etch to remove material from horizontal surfaces to complete the spacers 122.

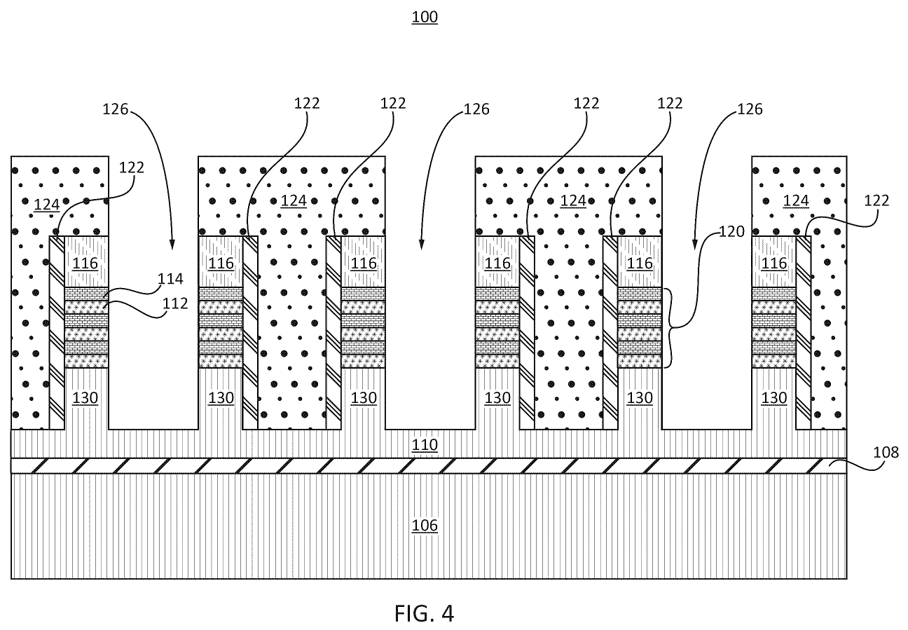

Referring to FIG. 4, a patternable material is deposited or spun onto a surface of the wafer 100. The patternable material can include an organic planarization layer (OPL) 124, which is formed over the wafer 100. In some embodiments, an anti-reflective coating (ARC) layer (not shown) may be formed on the OPL 124 followed by a layer of photoresist formed on the ARC layer. The layer of photoresist can be imaged with an image pattern and developed to form an etch mask. The OPL 124 can be etched in accordance with the etch mask to open up trenches 126 in the OPL 124, through the hard mask 116, through the stack 120 and into the semiconductor layer 110. The trenches 126 are etched by an anisotropic etch, e.g., a RIE etch or IBE etch.

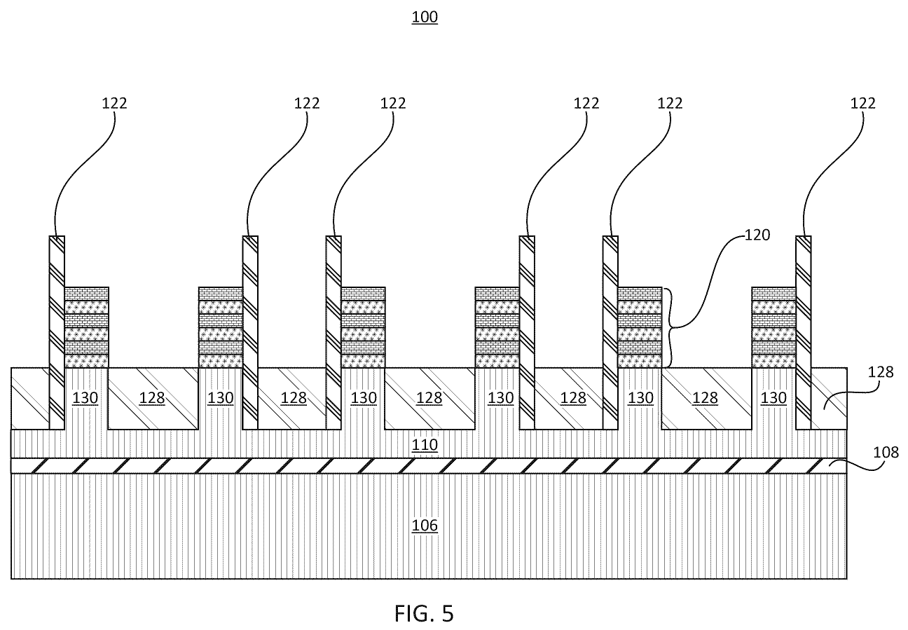

Referring to FIG. 5, shallow trench isolation (STI) or STI 128 are formed in the etched trenches. STI 128 can be formed by depositing dielectric material, such as, e.g., SiO₂, SiOₓN_{y}, SiCO or other suitable compounds. STI 128 can be deposited using CVD, although other deposition methods can be employed. The STI 128 can then be etched, e.g., by RIE, to a top level of the semiconductor layer 110. The OPL 124 and the hard mask 116 are removed.

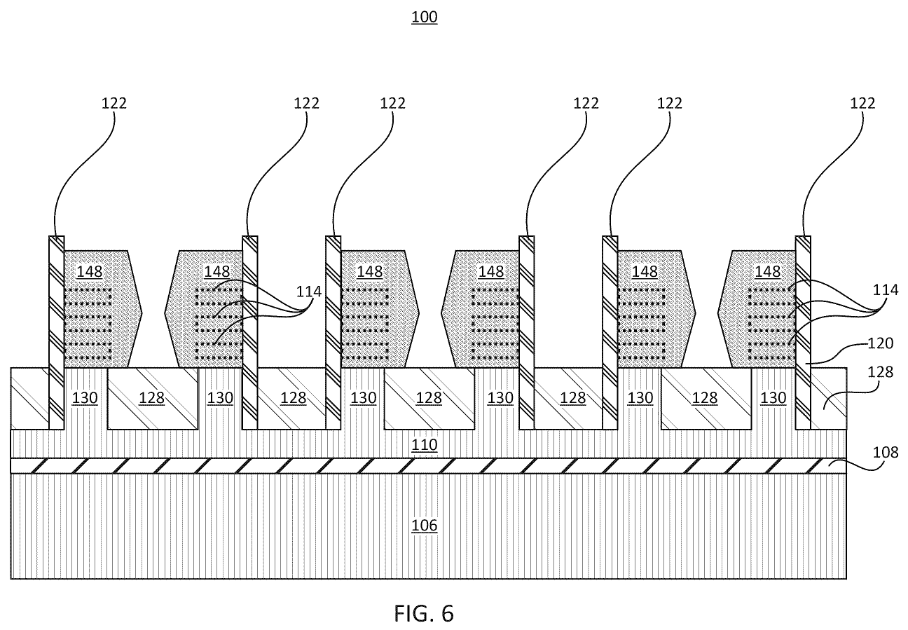

Referring to FIG. 6, processing continues with the formation of a dummy gate structures (not shown), gate spacers, and inner spacers. A dummy gate material can include a polysilicon, amorphous Si or other selectively removeable material. The dummy gate material is deposited followed by a hard mask material. The hard mask material is patterned to form a hard mask. The hard mask is employed to etch the dummy gates. Then, a deposition process is employed to form gate spacers. Gate spacers can include an oxide, such as silicon dioxide, although other dielectric materials can be employed. The hard mask and spacers can be employed as an etch mask to recess stacks 120 to expose semiconductor layer 110.

Inner spacers (not shown) are formed and include a dielectric material. The inner spacers are formed by recessing the semiconductor layer 112 and filling the recess with dielectric material. The inner spacers can include an oxide, such as silicon dioxide, although other dielectric materials can be employed. The remaining portions of the semiconductor layer 112 are removed.

An epitaxial growth process is performed to form bottom active regions or bottom source/drain (S/D) regions 148. Bottom S/D regions 148 are employed for bottom transistors of the stacked FET device under construction. Bottom S/D regions 148 can include Si or SiGe and include faceted surfaces when epitaxial growth is not confined.

The bottom S/D regions 148 are grown from exposed portions 130 of the semiconductor layer 110. The bottom S/D regions 148 grow unconfined on one side and confined by the spacers 122 or dielectric bars on the other. The spacers 122 or dielectric bars bound two adjacent S/D regions 148 on this level (e.g., bottom level). The spacers 122 or dielectric bars function as a boundary to confine epitaxial growth of the bottom S/D regions 148. It should be noted that the semiconductor layers 114 are depicted as projections with dashed lines to show relative positions of transistor channels with respect to the bottom S/D regions 148. The transistor channels formed by the semiconductor layers 114 are directed into/out of the page.

In an embodiment, the bottom S/D regions 148 can be designated as either P-type or N-type devices. The N-type devices can include Si, and P-type devices can include SiGe. The bottom S/D regions 148 can be appropriately doped during formation by epitaxial growth. For example, the bottom S/D regions 148 can be doped by introducing p dopants (e.g., B, Ga, etc.) during epitaxial formation. Similarly, the bottom S/D regions 148 can be doped by introducing n dopants (e.g., P, As, etc.) during epitaxial formation. In other embodiments, P-type and N-type devices can be formed adjacent to one another. Processing would include forming one device type and then the other device type by employing block masks to protect each device type during processing of the other.

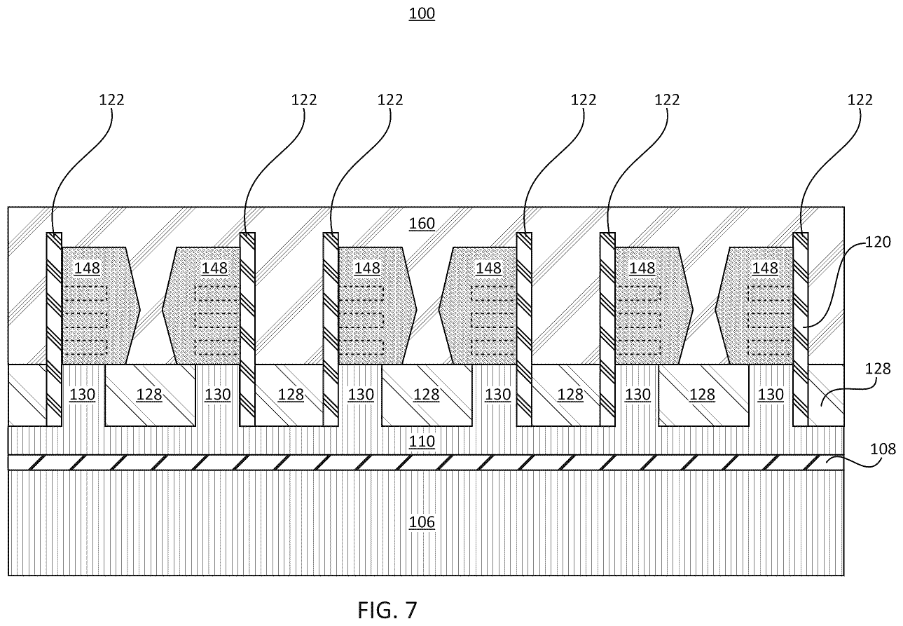

Referring to FIG. 7, a dielectric layer 160, such as, e.g., an interlevel dielectric layer (ILD) is formed on the wafer 100. The dielectric layer 160 can include any suitable material, e.g., selected from the group consisting of silicon containing materials such as SiO₂, Si₃N₄, SiOₓN_{y}, SiC, SiCO, SiCOH, and SiCH compounds, the above-mentioned silicon containing materials with some or all of the Si replaced by Ge, carbon doped oxides, inorganic oxides, inorganic polymers, hybrid polymers, organic polymers such as polyamides or SiLK™, other carbon containing materials, organo-inorganic materials such as spin-on glasses and silsesquioxane-based materials, and diamond-like carbon (DLC), also known as amorphous hydrogenated carbon, α-C:H). The dielectric layer 160 can be deposited using CVD, although other deposition methods can be employed. The dielectric layer 160 can be planarized using e.g., chemical mechanical polishing (CMP).

Processing continues with the removal of the dummy gate material and replacement metal gate formation for a bottom stack level of the wafer 100 to form High-K Metal Gates (HKMGs).

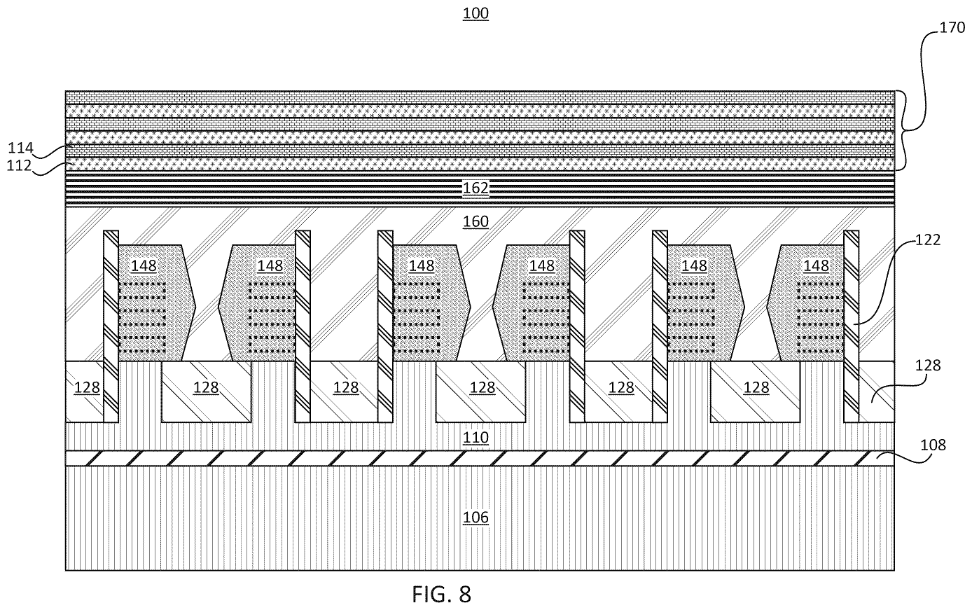

Referring to FIG. 8, a nanosheet 170 or stack can be bonded with a bonding layer 162 to facilitate the formation of a next level of stacked transistor structures. The bonding process can include applying a bonding layer 162 with the nanosheet 170 or stack on the wafer 100. The bonding layer 162 can include materials such as silicon dioxide, silicon oxynitride, or other suitable dielectric materials.

The bonding layer 162 can be subjected to thermal annealing to strengthen the bond between the bonding layer 162 and the wafer 100. The nanosheet 170 or stack includes semiconductor layers 112, 114, which will be employed in forming top FETs.

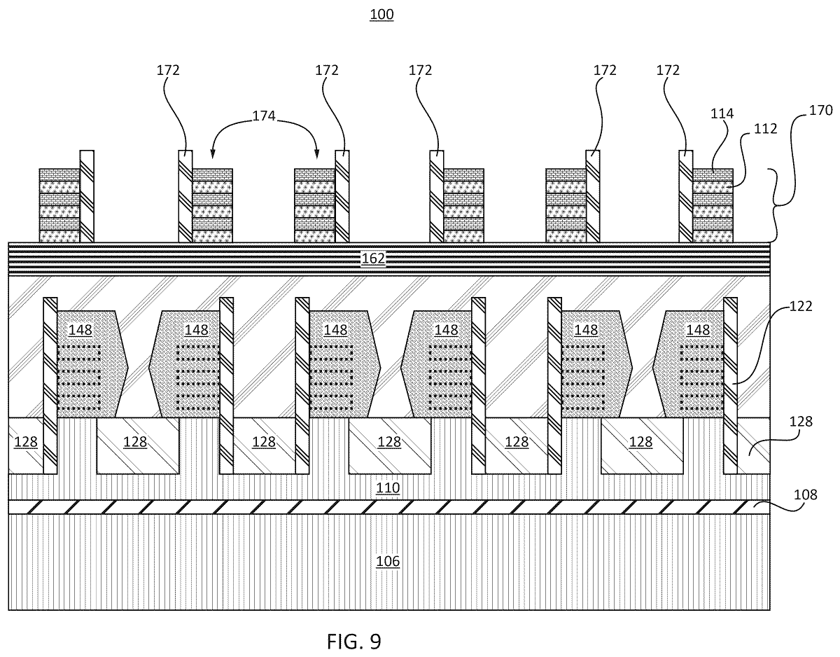

Referring to FIG. 9, the nanosheet 170 is patterned and etched using a suitable photolithographic patterning process. Spacers 172 are formed using a similar method as spacers 122. Then, a planarizing layer, such as OPL, is formed and patterned similarly to OPL 124, and the nanosheet 170 or stack is further etched to form structures 174 on a top level of the wafer 100.

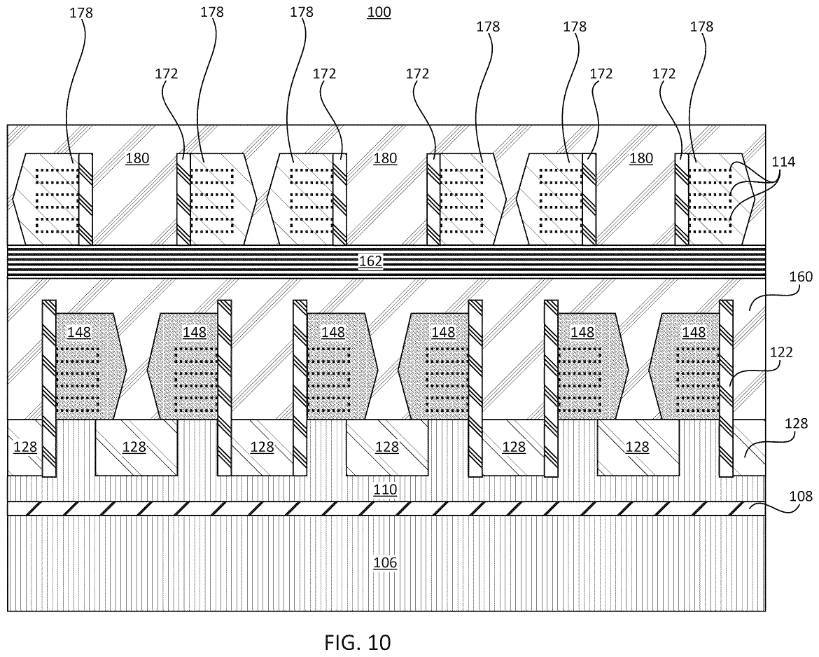

Referring to FIG. 10, as before, gate structures (not shown) are formed for the top level. This includes the deposition and patterning of dummy gate materials, gate spacer formation and nanosheet recessing. An epitaxial growth process is employed to grow top active regions or S/D regions 178. The top S/D regions 178 form S/D regions for top FETs for the stacked FET device under fabrication. The top S/D regions 178 can utilize the semiconductor layers 114 to initiate crystal growth. The top S/D regions 178 are separated from the bottom S/D regions 148 by the dielectric layer 160 and bonding layer 162.

It should be noted that the semiconductor layers 114 are depicted as projections with dashed lines to show relative positions of transistor channels with respect to the bottom S/D regions 178. The transistor channels formed by the semiconductor layers 114 are directed into/out of the page.

A dielectric layer 180 is deposited over the wafer 100. The same process used for the formation of dielectric layer 160 can be employed for dielectric layer 180, although dielectric layer 180 may include a different composition to enable etch selectivity. For example, if dielectric layer 160 includes a silicon oxide, dielectric layer 180 can include a silicon nitride to be selectively etchable with respect to dielectric layer 160. The dielectric layer 180 is planarized, e.g., by CMP. Processing continues with a replacement metal gate process to complete the gate structures (not shown) and form High-K Metal Gates (HKMGs).

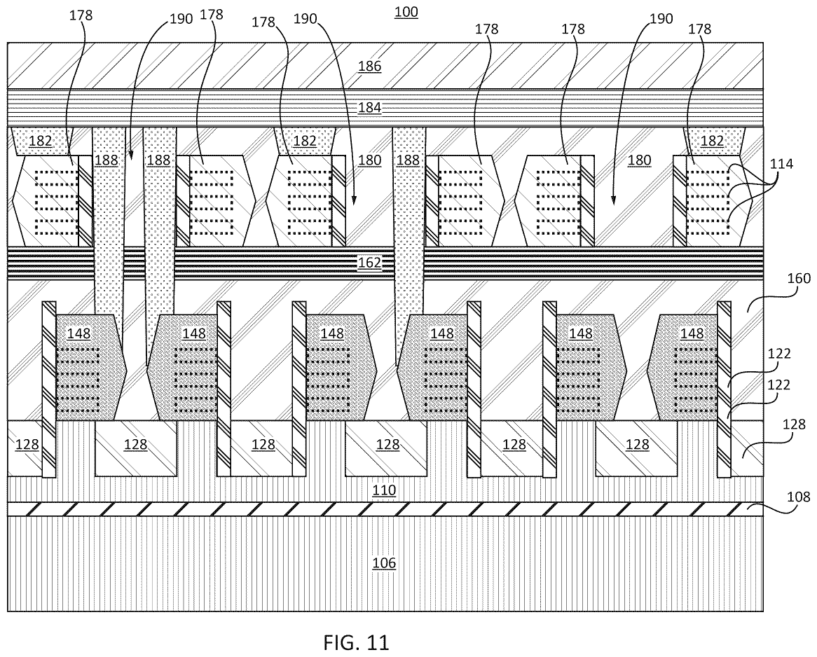

Referring to FIG. 11, contacts 182 are formed to make connections with the top S/D regions 178 from a top side of the wafer 100, and contacts 188 are formed to make connections with the bottom S/D regions 148 from a top side of the wafer 100. For contacts 182, trenches or holes are formed through the dielectric layer 180. The trenches or holes expose the underlying active materials for the top S/D regions 148. Contacts 188 are deep contacts that extend through the dielectric layer 180, the bonding layer 162 and into the dielectric layer 160 to connect to the bottom S/D regions 148. Note that the deep contacts 188 are disposed between the dielectric bars or spacers 172 at a top level. The dielectric bars or spacers 172 form wire channels 190 to permit passage of contacts with sufficient electrical insulation from top S/D regions 178.

In some embodiments, a silicide liner, such as Ti, Ni, NiPt is deposited in the trenches or holes before a conductive fill, then a diffusion barrier can be formed in the trenches prior to the conductive fill. The diffusion barrier can include, e.g., TiN, TaN, or similar materials.

A conductive fill is performed to fill the trenches on top of the diffusion barrier, if present. The conductive fill can include materials, such as, e.g., Cu, Ru, Mo, Rh, W, Ir, and alloys or combinations of these and other conductive materials. In a particularly useful embodiment, the conductive fill includes Cu. The conductive fill can be formed using a deposition method, such as, e.g., CVD, plasma enhanced CVD (PECVD), atomic layer deposition (ALD) or any other suitable deposition method. The conductive fill is planarized, e.g., by CMP, to form contacts 182, 188. The contacts 182, 188 can be formed concurrently or in separate processes. In some embodiments, the contacts 182 and/or 188 can join or connect to two adjacent S/D regions.

Processing continues with the formation of back end of the line (BEOL) layer 184, which can include metal structures and dielectric layers to complete the top side of the stacked FET device and provide electrical access to the devices formed. A carrier wafer 186 can be bonded to the BEOL layer 184. The carrier wafer 186 provides support and transportability to the wafer 100 for further processing which includes flipping the wafer 100 and removing portions of a bottom side of the stacked FET device.

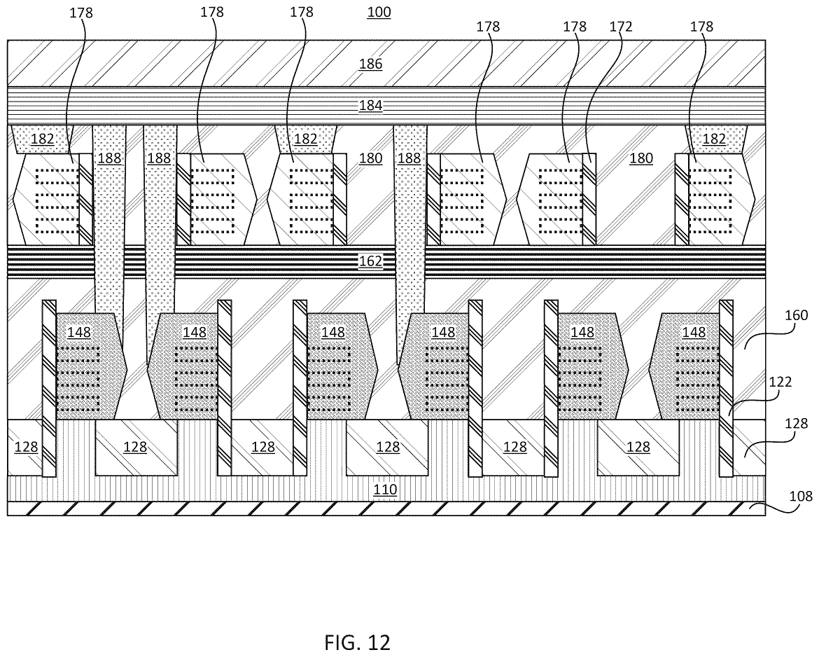

Referring to FIG. 12, to continue processing, the wafer 100 can be flipped to process features on the backside of the stacked FET device. However, for clarity and consistency, the stacked FET device will be shown in the FIGS. in a same orientation as previously described with continued and consistent reference to bottom/top, back/front. The substrate 106 is removed from the bottom side of the stacked FET device. The substrate 106 can be removed by an etch process that stops on the etch stop layer 108.

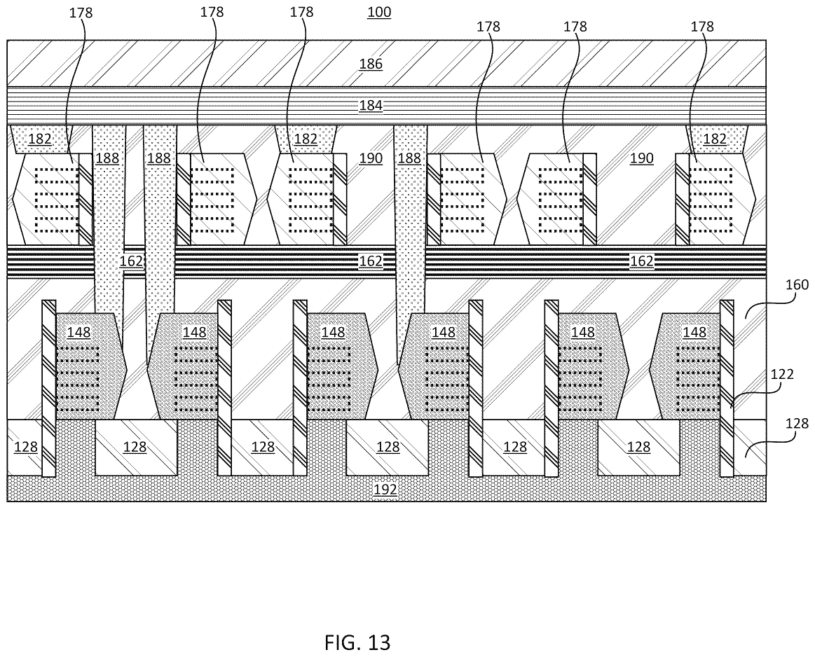

Referring to FIG. 13, the etch stop layer 108 is then removed by an etch process. In an alternate embodiment, a CMP process can be employed. With the removal of the etch stop layer 108, the semiconductor layer 110 is exposed. The semiconductor layer 110 is removed by an etch process that selectively removes the material of the semiconductor layer 110 relative to the STI 128, the bottom S/D regions 148 and the spacers 122 or dielectric bars.

A dielectric layer 192 is formed over the STI 128, the bottom S/D regions 148 and the spacers 122 or dielectric bars on a backside of the wafer 100. The dielectric layer 192 includes a material that is selectively removeable relative to the STI 128, the bottom S/D regions 148 and the spacers 122 or dielectric bars. The dielectric layer can include a similar material and formation process as that of dielectric layer 160 or dielectric layer 180. A planarization process (e.g., CMP) is performed to level off a free surface of the dielectric layer 192.

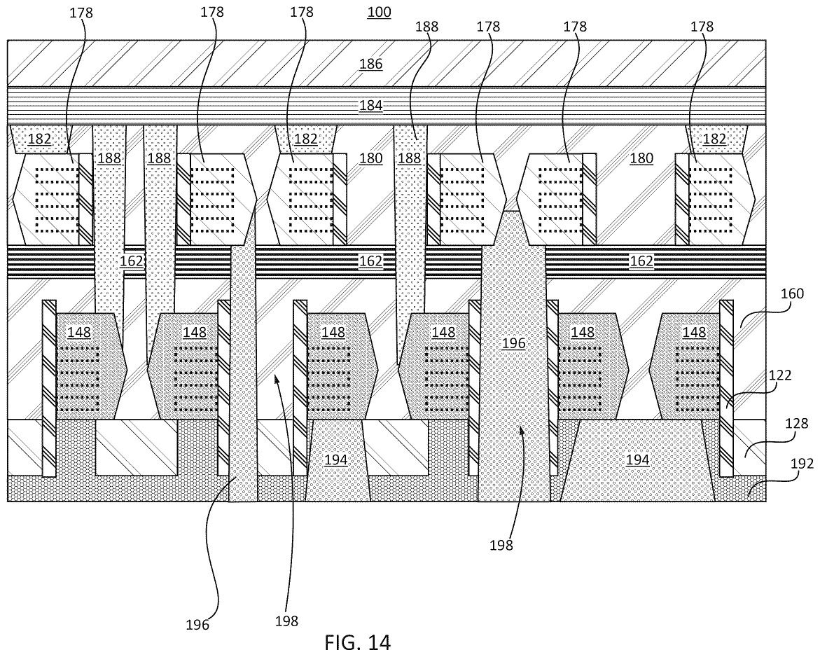

Referring to FIG. 14, backside contacts are formed to make connections with the bottom S/D regions 148 directly (contacts 194) from a backside of the wafer 100 and to make contact with top S/D regions 178 (contacts 196) across the bottom level of the stacked device. The contacts 196 are formed in wiring channels 198 which are bounded by the spacers 122 (dielectric bars). For contacts 194, trenches or holes are formed in the dielectric layer 192 and through the STIs 128 to expose bottom S/D regions 148. For contacts 196, trenches or holes are formed in the dielectric layer 192, through the STIs 128, dielectric layer 160, bonding layer 162 and into the dielectric layer 180. The trenches or holes can be patterned using photolithographic patterning techniques to create an etch mask to etch the trenches or holes with an anisotropic etch., e.g., RIE. The trenches or holes expose the underlying the bottom S/D regions 148 for direct contacts 194 and top S/D regions 178 for deep contacts 196.

A silicide liner, such as Ti, Ni, NiPt can be deposited in the trenches or holes, then a diffusion barrier can be formed prior to a conductive fill. The diffusion barrier can include, e.g., TiN, TaN, or similar materials. A conductive fill is performed to fill the trenches and holes. The conductive fill can include materials, such as, e.g., Cu, Ru, Mo, Rh, W, Ir, and alloys or combinations of these and other conductive materials. In a particularly useful embodiment, the conductive fill includes Cu. The conductive fill can be formed using a deposition method, such as, e.g., CVD, PECVD, ALD or any other suitable deposition method. The conductive fill is planarized, e.g., by CMP, to form the contacts 194 and the contacts 196 from the backside of the wafer 100. The contacts 194 and contacts 196 can be formed concurrently or in separate processes.

In some embodiments, the contacts 194 and/or 196 can join or connect two adjacent S/D regions. Using the backside of the wafer 100 can provide additional layout space, which can further permit larger sized contacts.

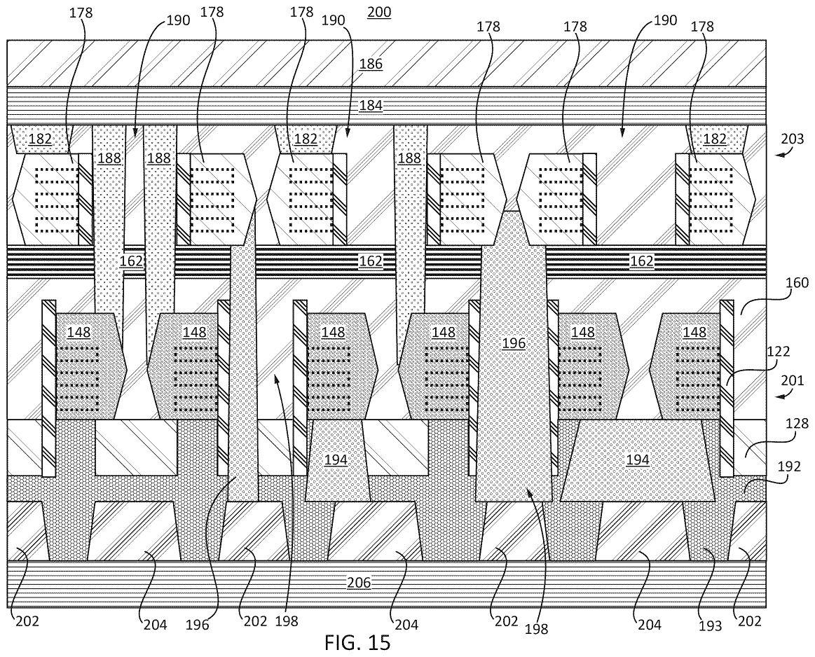

Referring to FIG. 15, the dielectric layer 192 is extended by forming additional dielectric material 193 to support the formation of backside power rails 202 and 204. The backside power rails 202, 204 can be formed by patterning the additional dielectric material 193 using photolithographic patterning techniques to create an etch mask to etch power rail openings with an anisotropic etch., e.g., RIE. The power rail openings expose the underlying contacts 194, 196.

A diffusion barrier can be formed in the power rail openings and can include, e.g., TiN, TaN, or similar materials. A conductive fill is performed to fill the trenches and holes. The conductive fill can include materials, such as, e.g., Cu, Ru, Mo, Rh, W, Ir, and alloys or combinations of these and other conductive materials. The conductive fill can be formed using a deposition method, such as, e.g., CVD, PECVD, ALD or any other suitable deposition method. The conductive fill is planarized, e.g., by CMP, to form the backside power rails 202 and 204 from the backside of the wafer 100. The backside power rails 202 and 204 can alternate between a positive supply voltage (e.g., VDD) and a negative supply voltages (e.g. VSS). Other configurations for the backside power rails 202 and 204 are also contemplated, e.g., adjacent power rails can include a same supply voltage potential.

A backside interconnect layer 206 is formed on and connects with the backside power rails 202 and 204. The backside interconnect layer 206 can include metal structures and dielectric layers to complete the bottom side of the stacked FET device and provide electrical access to the FET devices formed.

A stacked FET device 200 is provided having FETs formed in at least two levels 201 (top) and 203 (bottom). Top FETs include top S/D regions 178 that are offset from bottom S/D regions 148 without having to shift the top S/D regions 178 by too much. By confining epitaxial growth using dielectric bars (spacers 122 and 172) adequate spacing is preserved to permit deep contacts (contacts 188, 196) to extend across levels 201 and 203 to make contact with a S/D region of a different level. The contacts 188, 196 are electrically isolated from the S/D regions by the dielectric bars.

The dielectric bars on one level are formed on an opposite side of a corresponding S/D region on the other level. Said differently, a bottom S/D region 148 that has a dielectric bar (spacer 122) on a right side corresponds with a top S/D region 178 above it having a dielectric bar (spacer 172) on a left side. Further, a bottom S/D region 148 that has a dielectric bar (spacer 122) on a left side corresponds with a top S/D region 178 above it having a dielectric bar (spacer 172) on a right side. This pattern also includes wiring channels 190 alternating with wiring channels 198 between levels 201 and 203.

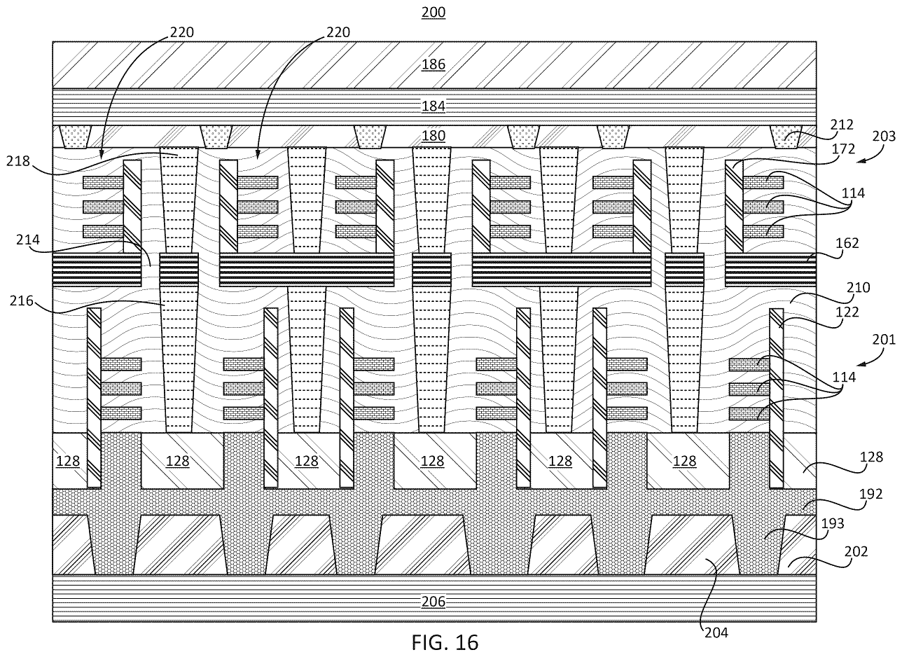

Referring to FIG. 16, a cross-sectional view through gate structures 220 of the stacked FET device is shown. The gate structures 220 are formed between S/D regions which would extend a depth into the page and the other S/D region extending a depth out of the page. Semiconductor layers 114 depicted as projections throughout FIGS. 1-15 would align with semiconductor layers 114 shown in FIG. 16.

Replacement metal gate structures 220 may be formed after removal of the dummy gate material. The replacement metal gate structures may include a high-k dielectric layer (not shown) deposited on semiconductor channel regions (semiconductor layers 114). The high-k dielectric layer may include materials such as hafnium oxide, zirconium oxide, or other metal oxides with a dielectric constant higher than silicon dioxide.

A work function metal layer may then be deposited on the high-k dielectric layer. The work function metal may be selected based on the desired threshold voltage for the transistor. For N-Type devices, metals such as titanium nitride, tantalum nitride, or aluminum may be used. For P-type devices, metals like titanium nitride with added aluminum, or platinum may be employed.

Following the work function metal, a low resistance metal fill may be deposited to complete the gate structure 220 and form gate electrodes 210. This metal fill may include materials such as tungsten, aluminum, or copper. The metal fill may be deposited using techniques like CVD or ALD. In some cases, multiple work function metal layers may be used to fine-tune the work function. Additionally, barrier layers or adhesion layers may also be incorporated between the various metal layers to improve interface quality and prevent inter-diffusion of materials.

Gate contacts 212 connect the gate electrodes 210 to the BEOL layer 184 so that the gate structures 220 can be selectively activated. Since the gate structures 220 are slightly offset between level 201 and level 203, there is a sufficient amount of overlap to form shared gate connections 214 between a gate structure 220 on level 201 and a gate structure 220 above it on level 203.

Gate cuts 216 and 218 are also shown which separate gate electrodes 210. The gate electrodes 210 incorporate and encapsulate the spacers 122 and spacers 172 therein. Note that the gate electrodes 210 are formed on both sides of each of spacers 122 and spacers 172.

Exemplary applications/uses to which the present invention can be applied include, but are not limited to semiconductor devices. Semiconductor devices can include processors, memory devices, application specific integrated circuits (ASICs), logic circuits or devices, combinations of these and any other circuit device. In such devices, one or more semiconductor devices can be included in a central processing unit, a graphics processing unit, and/or a separate processor-or computing element-based controller (e.g., logic gates, etc.). The semiconductor devices can include one or more on-board memories (e.g., caches, dedicated memory arrays, read only memory, etc.). In some embodiments, the semiconductor devices can include one or more memories that can be on or off board or that can be dedicated for use by a hardware processor subsystem (e.g., ROM, RAM, basic input/output system (BIOS), etc.).

In some embodiments, the semiconductor devices can include and execute one or more software elements. The one or more software elements can include an operating system and/or one or more applications and/or specific code to achieve a specified result. In still other embodiments, the semiconductor devices can include dedicated, specialized circuitry that perform one or more electronic processing functions to achieve a specified result. Such circuitry can include one or more field programmable gate arrays (FPGAs), and/or programmable applications programmable logic arrays (PLAs).

It is to be understood that aspects of the present invention will be described in terms of a given illustrative architecture; however, other architectures, structures, substrate materials and process features and steps can be varied within the scope of aspects of the present invention.

It will also be understood that when an element such as a layer, region or substrate is referred to as being “on” or “over” another element, it can be directly on the other element or intervening elements can also be present. In contrast, when an element is referred to as being “directly on” or “directly over” another element, there are no intervening elements present. It will also be understood that when an element is referred to as being “connected” or “coupled” to another element, it can be directly connected or coupled to the other element or intervening elements can be present. In contrast, when an element is referred to as being “directly connected” or “directly coupled” to another element, there are no intervening elements present.

The present embodiments can include a design for an integrated circuit chip, which can be created in a graphical computer programming language, and stored in a computer storage medium (such as a disk, tape, physical hard drive, or virtual hard drive such as in a storage access network). If the designer does not fabricate chips or the photolithographic masks used to fabricate chips, the designer can transmit the resulting design by physical means (e.g., by providing a copy of the storage medium storing the design) or electronically (e.g., through the Internet) to such entities, directly or indirectly. The stored design is then converted into the appropriate format (e.g., GDSII) for the fabrication of photolithographic masks, which typically include multiple copies of the chip design in question that are to be formed on a wafer. The photolithographic masks are utilized to define areas of the wafer (and/or the layers thereon) to be etched or otherwise processed.

Methods as described herein can be used in the fabrication of integrated circuit chips. The resulting integrated circuit chips can be distributed by the fabricator in raw wafer form (that is, as a single wafer that has multiple unpackaged chips), as a bare die, or in a packaged form. In the latter case, the chip is mounted in a single chip package (such as a plastic carrier, with leads that are affixed to a motherboard or other higher level carrier) or in a multichip package (such as a ceramic carrier that has either or both surface interconnections or backside interconnections). In any case, the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

It should also be understood that material compounds will be described in terms of listed elements, e.g., SiGe. These compounds include different proportions of the elements within the compound, e.g., SiGe includes SiₓGe₁₋ₓ where x is less than or equal to 1, etc. In addition, other elements can be included in the compound and still function in accordance with the present principles. The compounds with additional elements will be referred to herein as alloys.

Reference in the specification to “one embodiment” or “an embodiment”, as well as other variations thereof, means that a particular feature, structure, characteristic, and so forth described in connection with the embodiment is included in at least one embodiment. Thus, the appearances of the phrase “in one embodiment” or “in an embodiment”, as well any other variations, appearing in various places throughout the specification are not necessarily all referring to the same embodiment.

It is to be appreciated that the use of any of the following “/”, “and/or”, and “at least one of”, for example, in the cases of “A/B”, “A and/or B” and “at least one of A and B”, is intended to encompass the selection of the first listed option (A) only, or the selection of the second listed option (B) only, or the selection of both options (A and B). As a further example, in the cases of “A, B, and/or C” and “at least one of A, B, and C”, such phrasing is intended to encompass the selection of the first listed option (A) only, or the selection of the second listed option (B) only, or the selection of the third listed option (C) only, or the selection of the first and the second listed options (A and B) only, or the selection of the first and third listed options (A and C) only, or the selection of the second and third listed options (B and C) only, or the selection of all three options (A and B and C). This can be extended, as readily apparent by one of ordinary skill in this and related arts, for as many items listed.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements and/or components, but do not preclude the presence or addition of one or more other features, integers, steps, operations, elements, components and/or groups thereof.

Spatially relative terms, such as “beneath,” “below,” “lower,” “above,” “upper,” “top,” “bottom” and the like, can be used herein for ease of description to describe one element's or feature's relationship to another element(s) or feature(s) as illustrated in the FIGS. It will be understood that the spatially relative terms are intended to encompass different orientations of the device in use or operation in addition to the orientation depicted in the FIGS. For example, if the device in the FIGS. is turned over, elements described as “below” or “beneath” other elements or features would then be oriented “above” the other elements or features. Thus, the term “below” can encompass both an orientation of above and below. The device can be otherwise oriented (rotated 90 degrees or at other orientations), and the spatially relative descriptors used herein can be interpreted accordingly. In addition, it will also be understood that when a layer is referred to as being “between” two layers, it can be the only layer between the two layers, or one or more intervening layers can also be present.

It will be understood that, although the terms first, second, etc. can be used herein to describe various elements, these elements should not be limited by these terms. These terms are only used to distinguish one element from another element. Thus, a first element discussed below could be termed a second element without departing from the scope of the present concept.

Having described preferred embodiments of devices and methods (which are intended to be illustrative and not limiting), it is noted that modifications and variations can be made by persons skilled in the art in light of the above teachings. It is therefore to be understood that changes may be made in the particular embodiments disclosed which are within the scope of the invention as outlined by the appended claims. Having thus described aspects of the invention, with the details and particularity required by the patent laws, what is claimed and desired protected by Letters Patent is set forth in the appended claims.

1. A semiconductor device, comprising:
a first transistor in a first stacked level;
a second transistor in a second stacked level;
a first active region of the first transistor shifted with respect to a second active region of the second transistor;
a first dielectric bar confining the first active region on one side; and
a second dielectric bar confining the second active region on one side, wherein the first dielectric bar is on an opposite side of the second dielectric bar relative to corresponding active regions.

2. The semiconductor device of claim 1, further comprising a frontside deep contact extending through the first stacked level to connect with the second active region.

3. The semiconductor device of claim 1, further comprising a backside deep contact extending through the second stacked level to connect with the first active region.

4. The semiconductor device of claim 1, wherein adjacent first dielectric bars bound a wiring channel that permits passage of contacts, with electrical isolation, past the first active region.

5. The semiconductor device of claim 1, wherein adjacent second dielectric bars bound a wiring channel that permits passage of contacts, with electrical isolation, past the second active region.

6. The semiconductor device of claim 1, further comprising backside power rails formed on a backside of the semiconductor device and electrically connected to at least one of the first active region and the second active region.

7. A semiconductor device, comprising:
a first transistor level including first source/drain regions; and
a second transistor level including second source/drain regions, the second transistor level being stacked over the first transistor level;
wherein the first source/drain regions are shifted with respect to the second source/drain regions; and
wherein the first source/drain regions are confined on one side by first dielectric bars and the second source/drain regions are confined on one side by second dielectric bars, the first dielectric bars being on an opposite side of the second dielectric bars relative to respective source/drain regions.

8. The semiconductor device of claim 7, further comprising a frontside deep contact extending through the first transistor level to connect with a second source/drain region.

9. The semiconductor device of claim 7, further comprising a backside deep contact extending through the second transistor level to connect with a first source/drain region.

10. The semiconductor device of claim 7, wherein adjacent first dielectric bars bound a wiring channel that permits passage of contacts, with electrical isolation, past a first source/drain region.

11. The semiconductor device of claim 7, wherein adjacent second dielectric bars bound a wiring channel that permits passage of contacts, with electrical isolation, past a second source/drain region.

12. The semiconductor device of claim 7, further comprising backside power rails formed on a backside of the semiconductor device and electrically connected to at least one source/drain region.

13. The semiconductor device of claim 7, wherein the first source/drain regions and first dielectric bars follow a first alternating pattern in the first transistor level.

14. The semiconductor device of claim 13, wherein the second source/drain regions and second dielectric bars follow a second alternating pattern in the second transistor level.

15. The semiconductor device of claim 14, wherein the first alternating pattern and the second alternating pattern are offset from each other.

16. The semiconductor device of claim 7, further comprising gate structures formed on the first transistor level and in the second transistor level, the gate structures including a shared connection between the gate structures of the first transistor level and the gate structures of the second transistor level.

17. The semiconductor device of claim 16, wherein the gate structures in the first transistor level include gate electrodes that encapsulate the first dielectric bars.

18. A semiconductor device, comprising:
first transistors in a first stacked level;
second transistors in a second stacked level;
first source/drain regions of the first transistors being shifted with respect to second source/drain regions of the second transistors;
wherein the first source/drain regions are confined on one side by first dielectric bars and the second source/drain regions are confined on one side by second dielectric bars, the first dielectric bars being on an opposite side of the second dielectric bars relative to respective source/drain regions; and
wiring channels on one stacked level being aligned with unconfined sides of source/drain regions on an adjacent stacked level.

19. The semiconductor device of claim 18, wherein the wiring channels are bound by first dielectric bars on one stacked level and the second dielectric bars on another stacked level.

20. The semiconductor device of claim 19, further comprising a deep contact extending through one stacked level through a wiring channel to connect with a source/drain region on another stacked level.
